(19) United States
(12) Patent Application Publication
(10) Pub. No.: US 2018/0177079 A1
(43) Pub. Date: Jun. 21, 2018

(54) INFORMATION PROCESSING DEVICE AND ELECTRONIC DEVICE COOLING METHOD

(71) Applicant: FUJITSU LIMITED, Kawasaki-shi (JP)

(72) Inventors: Koji Nakagawa, Kawasaki (JP); Nobumitsu Aoki, Kawasaki (JP); Osamu Aizawa, Kasiwa (JP); Keita Hirai, Kawasaki (JP); Tsuyoshi So, Kawasaki (JP)

(73) Assignee: FUJITSU LIMITED, Kawasaki-shi (JP)

(21) Appl. No.: 15/832,947

(22) Filed: Dec. 6, 2017

(30) Foreign Application Priority Data
Dec. 20, 2016 (JP) 2016-246987
Aug. 3, 2017 (JP) 2017-150742

(51) Int. Cl. H05K 7/20

(52) U.S. Cl. CPC H05K 7/20781; H05K 7/20272

(57) ABSTRACT

An information processing device includes: a first distributing layer distributer configured to distribute a coolant for cooling electronic devices; and a second distributing layer distributer coupled to the first distributing layer distributer and configured to distribute the coolant, wherein the first distributing layer distributer includes a first distributing pipe and first distributing connecting pipes branched from the first distributing pipe, the first distributing pipe is disposed so that an axis of the first distributing pipe is parallel with the height direction, and the first distributing connecting pipes are arranged in the height direction, wherein the second distributing layer distributer includes second distributing pipes which are coupled to the respective first distributing connecting pipes, each of the second distributing pipes is disposed so that an axis of the second distributing pipe is parallel with the height direction, and the second distributing pipes are arranged in the height direction.

### CROSS-REFERENCE TO RELATED APPLICATION

This application is based upon and claims the benefit of priority of the prior Japanese Patent Application Nos. 2017-150742, filed on Aug. 3, 2017, and 2016-246987, filed on Dec. 20, 2016, the entire contents of which are incorporated herein by reference.

### FIELD

The embodiment discussed herein is related to an information processing device and an electronic device cooling method.

### BACKGROUND

In an information processing device such as a server device or the like, a coolant supply device supplies a coolant into the information processing device by using metal piping, resin hoses, and the like to cool electronic devices or the like included in the information processing device.

A related technology is disclosed in Japanese Laid-open Patent Publication No. 2001-343174.

### SUMMARY

According to an aspect of the embodiment, an information processing device includes: a first distributing layer distributer configured to distribute a coolant for cooling a plurality of electronic devices stacked in a height direction; and a second distributing layer distributer coupled to the first distributing layer distributer and configured to distribute the coolant, wherein the first distributing layer distributer includes a first distributing pipe which temporarily stores the coolant and a plurality of first distributing connecting pipes branched from the first distributing pipe, the first distributing pipe is disposed in such a manner that an axis of the first distributing pipe is parallel with the height direction, and the plurality of first distributing connecting pipes are arranged side by side in the height direction, wherein the second distributing layer distributer includes a plurality of second distributing pipes which are coupled to the respective first distributing connecting pipes and temporarily store the coolant, each of the plurality of second distributing pipes is disposed in such a manner that an axis of the second distributing pipe is parallel with the height direction, and the plurality of second distributing pipes are arranged in the height direction.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of an information processing device including a distributing unit and a merging unit;

FIG. 2 illustrates an example of an information processing device including a distributing unit and a merging unit;

FIG. 3 is an example of a perspective view of a part of a distributing unit and a merging unit;

FIG. 4 is an example of a plan view of an electronic device;

FIG. 5 illustrates an example of distribution and merging of a coolant; and

FIG. 6 illustrates an example of an information processing device.

### DESCRIPTION OF EMBODIMENT

In a server device, a coolant is distributed to cool each of a plurality of electronic devices that each include a central processing unit (hereinafter a CPU). The coolant is, for example, distributed by a distributing unit in which distribution paths such as a plurality of hoses or the like are coupled to one thick pipe (which distributing unit is referred to also as a multiple-branch pipe or a manifold).

As the number of electronic devices included in the server device is increased, for example, the piping length of the distributing unit is increased to evenly distribute the coolant to the electronic devices, and therefore the mounting space of the distributing unit may be enlarged.

An information processing device in which the whole of a distributing unit distributing a coolant is miniaturized, for example, may be provided.

In the following, the same or similar elements are identified by common reference symbols, and the scale of the drawings may be changed as appropriate in order to facilitate understanding.

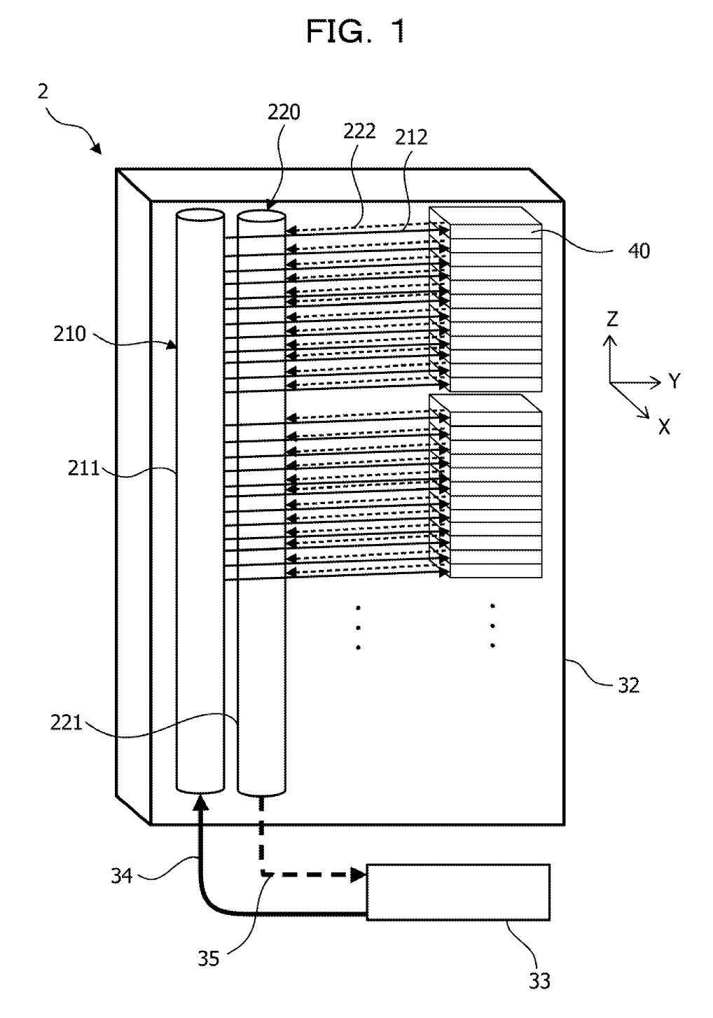

FIG. 1 illustrates an example of an information processing device including a distributing unit and a merging unit. The information processing device illustrated in FIG. 1 may be a server device. Provided within a casing 32 of a server device 2 are a plurality of electronic devices 40 each including a CPU, a heat exchanger 33, a distributing unit 210 that distributes a coolant, and a merging unit 220 that collects the coolant after cooling the electronic devices 40.

The distributing unit 210 is coupled to the heat exchanger 33 by a feed pipe 34. The coolant flows from the heat exchanger 33 through the feed pipe 34 into the distributing unit 210. The heat exchanger 33 is also a coolant feeder, and has a function of a pump that sends the coolant to the distributing unit 210.

The distributing unit 210 is a device that distributes the coolant sent from the heat exchanger 33 to the electronic devices 40. The distributing unit 210 includes a distributing pipe 211 into which the coolant flows and distributing connecting pipes 212 as communication paths between the distributing pipe 211 and the electronic devices 40. In FIG. 1, the distributing connecting pipes 212 are represented by solid lines, and arrows thereof indicate a flow direction of the coolant. The distributing pipe 211 includes one inlet coupled to the feed pipe 34 and outlets equal in number to the number of the electronic devices 40. The distributing connecting pipes 212 are, for example, hoses made of a resin. The distributing connecting pipes 212 are coupled to the outlets provided to the distributing pipe 211 and inlets provided to the respective electronic devices 40. The cooling water flowing from the heat exchanger 33 through the feed pipe 34 into the distributing unit 210 is stored in the distributing pipe 211, and distributed to each of the electronic devices 40 through the distributing connecting pipes 212.

The merging unit 220 includes a merging pipe 221 and merging connecting pipes 222 as communication paths between the electronic devices 40 and the merging pipe 221. In FIG. 1, the merging connecting pipes 222 are represented by dotted lines, and arrows thereof indicate a flow direction of the coolant. The cooling water flowing out from the electronic devices 40 is collected by the merging pipe 221 via the merging connecting pipes 222. The cooling water collected by the merging pipe 221 flows from the merging pipe 221 through a drain pipe 35 into the heat exchanger 33. The cooling water heated by the electronic devices 40 is cooled by the heat exchanger 33 again, and sent to the distributing unit 210 by the heat exchanger 33 again. The cooling water thus circulates to cool the electronic devices 40 in the server device 2.

The structure that distributes the coolant to the electronic devices 40 using the distributing pipe 211 branching into the plurality of distributing connecting pipes 212 supplies the plurality of electronic devices 40 with the coolant at substantially equal temperatures and substantially equal flow rates. As the performance of the server device 2 is enhanced, for example, more electronic devices 40 each including a CPU are incorporated, and the size of the server device 2 may be increased due to the following factors.

(1) Because one distributing pipe 211 branches so as to couple to the plurality of electronic devices 40, the length of the distributing pipe 211 is increased as the number of electronic devices 40 is increased. In order to reduce pressure losses caused by difference between distances from the inlet of the distributing pipe 211 to the electronic devices 40 (which distances may hereinafter be referred to as distribution paths), the distribution paths desirably have a same length. Therefore, the lengths of all of the distributing connecting pipes 212 are adjusted to the length of a longest distributing connecting pipe 212. Thus, a larger mounting space may be provided.

(2) Pressure losses due to increases in distance from the inlet of the distributing pipe 211 to the individual outlets of the distributing pipe 211 invite decreases in flow rate. Thus, in order to reduce difference between the pressure losses, the diameter of the distributing pipe 211 may be further increased.

With the structure of the distributing unit 210 and the merging unit 220 illustrated in FIG. 1, the mounting space is increased in size as the electronic devices 40 to be cooled are increased in number. The installation area of a server device is often limited. It may thus be difficult to increase the exclusive area for the distributing unit 210 and the merging unit 220. Therefore, a small distributing unit and a small merging unit that occupy a smaller mounting space may be provided.

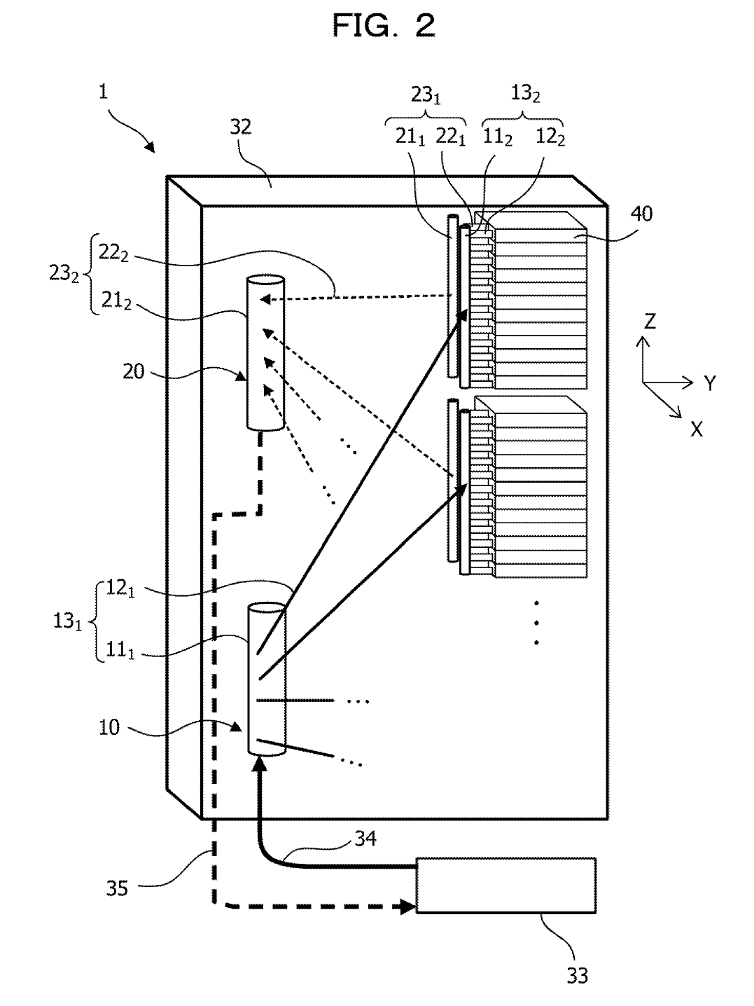

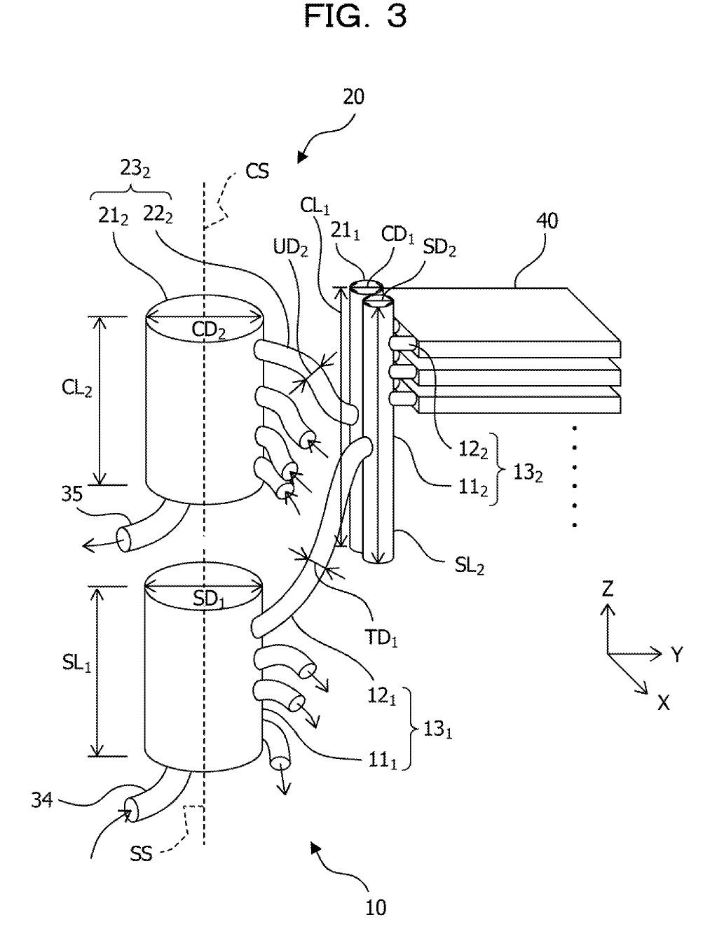

FIG. 2 illustrates an example of an information processing device including a distributing unit and a merging unit. The information processing device illustrated in FIG. 2 may be a server device 1. FIG. 3 is an example of a perspective view of a part of a distributing unit and a merging unit. A Z-axis illustrated in FIG. 2 and FIG. 3 represents a height direction of the server device 1. As with the server device 2 illustrated in FIG. 1, the server device 1 includes a plurality of electronic devices 40 each including a CPU and a heat exchanger 33. The server device 1 further includes a distributing unit 10 that distributes, to each of the electronic devices 40, a coolant sent from the heat exchanger 33 via a feed pipe 34, and a merging unit 20 that collects the coolant after cooling the electronic devices 40.

As illustrated in FIG. 2 and FIG. 3, the distributing unit 10 has a hierarchical structure in two stages, and includes two distributing layer distributing units 13₁ and 13₂ (the plurality of distributing layer distributing units may hereinafter be collectively referred to simply as distributing layer distributing units 13) coupled to each other.

For example, the distributing unit 10 includes the first distributing layer distributing unit 13₁ that distributes the coolant from the feed pipe 34, and the second distributing layer distributing unit 13₂ that is coupled to the first distributing layer distributing unit 13₁ and further distributes the coolant. The first distributing layer distributing unit 13₁ includes a distributing pipe 11₁ that temporarily stores the coolant, and a plurality of distributing connecting pipes 12₁ branched from the distributing pipe 11₁. The distributing connecting pipes 12₁ are indicated by solid line arrows in FIG. 2. The arrows indicate a flow direction of the coolant. The second distributing layer distributing unit 13₂ includes a distributing pipe 11₂ coupled to each of the distributing connecting pipes 12₁ of the first distributing layer distributing unit 13₁, and a plurality of distributing connecting pipes 12₂ branched from the distributing pipe 11₂. Each of the plurality of distributing connecting pipes 12₂ of the second distributing layer 13₂ is coupled to a corresponding electronic device 40. In the following, the plurality of distributing pipes 11₁ and 11₂ and the plurality of distributing connecting pipes 12₁ and 12₂ may be referred to collectively as distributing connecting pipes 12.

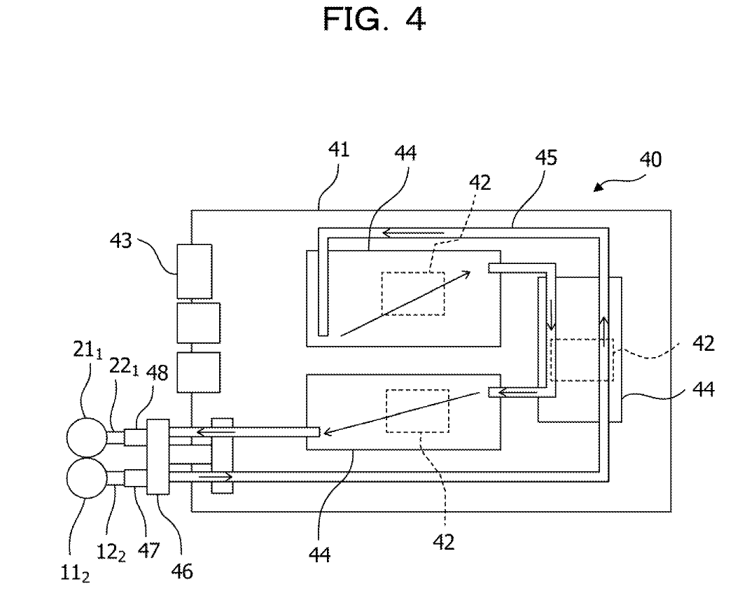

The heat exchanger 33 is coupled to the distributing pipe 11₁ present in the first distributing layer 13₁ via the feed pipe 34. The distributing pipe 11₁ branches into four distributing connecting pipes 12₁. The distributing pipe 11₁ is provided with a plurality of outlets for one inlet. The distributing connecting pipes 12₁ of the first distributing layer distributing unit 13₁ on an upstream side are each coupled to the distributing pipe 11₂ of the second distributing layer distributing unit 13₂ on a downstream side. The distributing connecting pipe 12₁ is provided with one outlet for one inlet. The distributing pipe 11₂ of the second distributing layer distributing unit 13₂ branches into a plurality of distributing connecting pipes 12₂. The distributing connecting pipes 12₂ are individually coupled to inlets 47 (see FIG. 4) of the electronic devices 40.

As illustrated in FIG. 3, a diameter TD₁ of the distributing connecting pipes 12₁ of the first distributing layer distributing unit 13₁ is formed so as to be smaller than a diameter SD₁ of the distributing pipe 11₁ of the first distributing layer distributing unit 13₁. A diameter SD₂ of the distributing pipe 11₂ of the second distributing layer distributing unit 13₂ on the downstream side is formed so as to be smaller than the diameter SD₁ of the distributing pipe 11₁ of the first distributing layer distributing unit 13₁ on the upstream side.

When a single distributing pipe is used as in the server device 2 illustrated in FIG. 1, the single distributing pipe is branched so as to distribute the coolant to all of the electronic devices. Forming the distributing unit 10 into a hierarchical structure as in the server device 1 illustrated in FIG. 2, for example, may reduce the number of branches in each of the distributing pipes 11. Because the number of branches is decreased, the length of all of the distributing connecting pipes 12 may not be lengthened to reduce pressure losses.

Therefore, a space occupying rate of the distributing connecting pipes 12 may be reduced. Because a flow rate per distributing pipe 11 is decreased, the diameter SD of the distributing pipes 11 may be reduced. Therefore, the distributing unit 10 as a whole may be more miniaturized, and parts cost may be reduced.

As with the distributing unit 10, the merging unit 20 has a hierarchical structure as illustrated in FIG. 2 and FIG. 3. The merging unit 20 illustrated in FIG. 2 includes merging layer merging units 23₁ and 23₂ in two layers. The merging layer merging units 23₁ and 23₂ include merging pipes 21₁ and 21₂ and merging connecting pipes 22₁ and 22₂ (represented by dotted line arrows in FIG. 2, the arrows indicating a flow direction of the coolant). In the merging unit 20 illustrated in FIG. 2, the coolant discharged from the electronic devices 40 is stored in the merging pipe 21₁ via the merging connecting pipes 22₁. The temporarily stored coolant flows into the merging pipe 21₂ of the second merging layer merging unit 23₂ on the downstream side via the merging connecting pipes 22₂. The coolant collected by the merging pipe 21₂ flows into the heat exchanger 33 via a drain pipe 35.

As illustrated in FIG. 3, a diameter CD₂ of the merging pipe 21₂ of the second merging layer merging unit 23₂ is formed so as to be larger than a diameter CD₁ of the merging pipe 21₁ of the first merging layer merging unit 23₁. A diameter UD₁ of the merging connecting pipes 22₁ of the first merging layer merging unit 23₁ is formed so as to be smaller than the diameter CD₁ of the merging pipe 21₁ in a first layer. Because of the division into layers, the quantity of the coolant flowing into the merging pipe 21₁ on the upstream side is reduced, and the diameter CD₁ of the merging pipe 21₁ of the first merging layer merging unit 23₁ may be smaller than the diameter CD₂ of the merging pipe 21₂ of the second merging layer merging unit 23₂.

FIG. 4 is an example of a plan view of an electronic device. FIG. 4 illustrates an electronic device cooled by the coolant. As illustrated in FIG. 4, in the electronic device 40, a plurality of integrated circuits 42 of a CPU and the like are mounted on a printed board 41. Electric connectors 43 for coupling to another electronic device and the like are arranged at an end portion of the printed board 41. Cold plates 44 for cooling the integrated circuits 42, which are heat generating parts, are attached to the integrated circuits 42. A pipe 45 through which the coolant flows is disposed so as to efficiently cool the cold plates 44 on the integrated circuits 42. The electronic device 40 is provided with a coupler 46 for coupling to the distributing connecting pipe 12₂ of the distributing unit 10 and the merging connecting pipe 22₁ of the merging unit 20. The coupler 46 includes an inlet 47 and an outlet 48, which are coupled with respective end portions of the pipe 45 for circulating the coolant. The electronic device 40 may be attached to the distributing unit 10 and the merging unit 20 easily by fitting the inlet 47 provided to the coupler 46 with the distributing connecting pipe 12₂ and fitting the outlet 48 with the merging connecting pipe 22₁. The coolant flows within the pipe 45 according to arrows illustrated in FIG. 4.

The size of the distributing unit 210 and the merging unit 220 of the server device 2 illustrated in FIG. 1 is compared with the size of the distributing unit 10 and the merging unit 20 of the server device 1 illustrated in FIG. 2. The size of the distributing unit and the merging unit needed to cool 96 electronic devices 40, for example, is illustrated. The distributing unit 10 of the server device 1 has two layers, as illustrated in FIG. 2. Eight distributing connecting pipes 12₁ are coupled to the distributing pipe 11₁ of the first distributing layer distributing unit 13₁, and thus the coolant is branched into eight paths. Distributing pipes 11₂ of the second distributing layer distributing unit 13₂ are coupled to the respective distributing connecting pipes 12₁. For example, the second distributing layer distributing unit 13₂ is provided with eight distributing pipes 11₂. Each of the distributing pipes 11₂ of the second distributing layer distributing unit 13₂ is branched into 12 pipes, which are coupled to electronic devices 40 as illustrated in FIG. 4. Twelve electronic devices 40 are arranged in parallel with one another as illustrated in FIG. 2 for one distributing pipe 11₂, and inlets 47 of the respective electronic devices 40 are arranged in one column. Thus, the electronic devices 40 are directly coupled without the use of additional hoses or the like.

The diameter SD₁ of the distributing pipe 11₁ of the first distributing layer distributing unit 13₁ is set at 45 mm. A length SL₁ in a longitudinal direction of the distributing pipe 11₁ of the first distributing layer distributing unit 13₁ is set at 400 mm. The following Equation is used to set the diameter SD₂ of the distributing pipes 11₂ of the second distributing layer distributing unit 13₂.

SD₂=SD₁/√SN₁

where SD₂ denotes the diameter of the distributing pipes 11₂ of the second distributing layer distributing unit 13₂, SD₁ denotes the diameter of the distributing pipe 11₁ of the first distributing layer distributing unit 13₁, and SN₁ denotes the number of branches from the distributing pipe 11₁ of the first distributing layer distributing unit 13₁ to the distributing pipes 11₂ of the second distributing layer distributing unit 13₂.

Because the distributing pipe 11₁ of the first distributing layer distributing unit 13₁ branches into eight pipes of the second distributing layer distributing unit 13₂, for example, a flow rate at which the coolant passes through each of the distributing pipes 11₂ of the second distributing layer distributing unit 13₂ is ⅛ of a flow rate at which the coolant passes through the distributing pipe 11₁ of the first distributing layer distributing unit 13₁. In order to suppress pressure losses in the distributing pipes 11₂ of the second distributing layer distributing unit 13₂ to a similar level to that of the distributing pipe 11₁ of the first distributing layer distributing unit 13₁, a cross-sectional area of the distributing pipes 11₂ of the second distributing layer distributing unit 13₂ is set at approximately ⅛ of a cross-sectional area of the distributing pipe of the first distributing layer distributing unit 13₁, as in the case of the flow rates. For example, the cross-sectional area ratio is ⅛, and an inside diameter ratio is √(⅛). When distribution and cost aspects are considered while the above is taken into consideration, the diameter SD₂ of the distributing pipes 11₂ in a second layer is set at 20 mm, and a pipe length SL₂ of the distributing pipes 11₂ is set at 400 mm. A diameter of the distributing connecting pipes 12₁ (hoses) coupling the distributing pipe 11₁ of the first distributing layer distributing unit to the distributing pipes 11₂ of the second distributing layer distributing unit is set at 15 mm, and a length of the distributing connecting pipes 12₁ is set at 1500 mm. The merging unit 20 is formed with similar dimensions because the merging unit 20 collects the cooling water fed into each of the electronic devices 40 by the distributing unit 10. For example, the diameter CD₁ of the merging pipe 21₁ of the first merging layer merging unit 23₁ is set at 20 mm, a pipe length CL₁ of the merging pipe 21₁ of the first merging layer merging unit 23₁ is set at 400 mm, the diameter CD₂ of the merging pipe 21₂ of the second merging layer merging unit 23₂ is set at 45 mm, and a pipe length CL₂ of the merging pipe 21₂ of the second merging layer merging unit 23₂ is set at 400 mm. A diameter of the merging connecting pipes 22₂ is set at 15 mm, and a length of the merging connecting pipes 22₂ is set at 1500 mm.

A volume in a case where the distributing unit 10 and the merging unit 20 are fabricated with the above-described dimensions is illustrated in Table 1.

TABLE 1

| | | | Pipe cross- | | Pipe | | |
|---|---|---|---|---|---|---|---|
| | | Pipe | sectional | Pipe | volume | | Pipe |
| | | diameter | area | length | per pipe | | volume |
| | | (mm) | (mm²) | (mm) | (mm³) | Number | (mm³) |
| Distributing | Distributing | 45 | 1590.4 | 400 | 636,172.5 | 1 | 636,172.5 |
| unit | pipe of first | | | | | | |
| | distributing | | | | | | |
| | layer | | | | | | |
| | distributing | | | | | | |
| | unit | | | | | | |
| | Distributing | 20 | 314.2 | 400 | 125,663.7 | 12 | 1,507,964.5 |
| | pipes of | | | | | | |
| | second | | | | | | |
| | distributing | | | | | | |
| | layer | | | | | | |
| | distributing | | | | | | |
| | unit | | | | | | |
| | Distributing | 15 | 176.7 | 1500 | 265,071.9 | 8 | 2,120,575.0 |
| | connecting | | | | | | |
| | pipes of first | | | | | | |
| | distributing | | | | | | |
| | layer | | | | | | |
| | distributing | | | | | | |
| | unit | | | | | | |
| Merging | Merging pipes | 20 | 314.2 | 400 | 125,663.7 | 12 | 1,507,964.5 |
| unit | of first | | | | | | |
| | merging layer | | | | | | |
| | merging unit | | | | | | |
| | Merging pipe | 45 | 1590.4 | 400 | 636,172.5 | 1 | 636,172.5 |
| | of second | | | | | | |
| | merging layer | | | | | | |
| | merging unit | | | | | | |
| | Merging | 15 | 176.7 | 1500 | 265,071.9 | 8 | 2,120,575.0 |
| | connecting | | | | | | |
| | pipes of | | | | | | |
| | second | | | | | | |
| | merging layer | | | | | | |
| | merging unit | | | | | | |

Total volume 8,529,424.1

When the distributing unit 210 illustrated in FIG. 1 distributes the coolant to 96 electronic devices 40, the cross-sectional area of the distributing unit 210 is set equal to or more than four times the cross-sectional area of the distributing pipe 11₁ of the first distributing layer distributing unit 13₁. Therefore, a diameter of the distributing pipe 21₁ is set at 90 mm, and a length of the distributing pipe 21₁ is set at 1600 mm. A diameter of the distributing connecting pipes 21₂ (hoses) that establish coupling from the distributing unit 210 to the electronic devices 40 is set at 10 mm, and a length of the distributing connecting pipes 21₂ is set at 500 mm. The merging unit 220, which collects the cooling water after cooling the electronic devices 40, is disposed with dimensions similar to those of the distributing unit 210. For example, a diameter of the merging pipe 22₁ is set at 90 mm, a pipe length of the merging pipe 22₁ is set at 1600 mm, a diameter of the merging connecting pipes 22₂ is set at 10 mm, and a pipe length of the merging connecting pipes 22₂ is set at 500 mm.

A volume in a case where the distributing unit and the merging unit are fabricated with the above-described dimensions is illustrated in Table 2.

TABLE 2

| | | | Pipe cross- | | Pipe | | |
|---|---|---|---|---|---|---|---|
| | | Pipe | sectional | Pipe | volume | | Pipe |
| | | diameter | area | length | per pipe | | volume |
| | | (mm) | (mm²) | (mm) | (mm³) | Number | (mm³) |
| Distributing | Distributing | 90 | 6,361.7 | 1600 | 10,178,760.2 | 1 | 10,178,760.2 |
| unit | pipe | | | | | | |
| | Distributing | 10 | 78.5 | 500 | 39,269.9 | 96 | 3,769,911.2 |
| | connecting | | | | | | |
| | pipes | | | | | | |
| Merging | Merging | 90 | 6,361.7 | 1600 | 10,178,760.2 | 1 | 10,178,760.2 |
| unit | pipe | | | | | | |
| | Merging | 10 | 78.5 | 500 | 39,269.9 | 96 | 3,769,911.2 |
| | connecting | | | | | | |
| | pipes | | | | | | |

Total volume 27,897,342.8

A comparison of the volume of the distributing unit 10 and the merging unit 20 of the server device 1 which volume is illustrated in Table 1 with the volume of the distributing unit 210 and the merging unit 220 of the server device 2 which volume is illustrated in Table 2 indicates that a volume reduction to approximately ⅓ may be achieved. Therefore, for example, when the server device 1 illustrated in FIG. 2 is used, pressure losses may be reduced to a similar level to those of the server device 2 illustrated in FIG. 1 while the coolant is distributed to many electronic devices 40 and the coolant is collected. For example, the server device 1 illustrated in FIG. 2 may reduce the volume desired for piping while maintaining cooling performance.

In the server device 2 illustrated in FIG. 1, the distributing pipe 211 and the merging pipe 221 are arranged in parallel with each other. In the server device 1 illustrated in FIG. 2, a length of the distributing pipe 11₁ and the merging pipe 21₂ may be half that of the distributing pipe 211 and the merging pipe 221 of the server device 2 illustrated in FIG. 1. Therefore, the distributing pipe 11₁ and the merging pipe 21₂ may be arranged vertically, or, for example, arranged such that a longitudinal axis SS of the distributing pipe 11₁ and a longitudinal axis CS of the merging pipe 21₂ are the same axis, as illustrated in FIG. 2 and FIG. 3. Therefore, an installation space of the distributing unit 10 and the merging unit 20 may become smaller than that of the distributing unit 210 and the merging unit 220 of the server device 2 illustrated in FIG. 1.

The distributing unit 10 and the merging unit 20 illustrated in FIG. 2 and FIG. 3 are formed by distributing layer distributing units and merging layer merging units in two layers. For example, the distributing unit 10 and the merging unit 20 may be formed in two layers, and besides, may be formed in three layers or more according to the number of coupled electronic devices 40.

When the layers of the distributing layer distributing units are generalized, and, for example, referred to as N layers (N is a layer number and an integer of one or more, and increases from the upstream side, from which the coolant flows, to the downstream side), a distributing layer distributing unit 13_{N} includes a distributing pipe 11_{N} that stores the coolant temporarily and a plurality of distributing connecting pipes 12_{N} coupled to distributing pipes 11_{N+1} or electronic devices 40 on the downstream side.

The merging unit 20 is not limited to two layers either, and may be formed in three layers or more according to the number of coupled electronic devices 40. A merging layer merging unit 23_{M} (M is a layer number, and increases from the upstream side, from which the coolant flows, to the downstream side) includes a merging pipe 21_{M} that stores the coolant temporarily and a plurality of merging connecting pipes 22_{M} coupled to the electronic devices 40 or merging pipes 21_{M-1} of merging layer merging units on the upstream side. Each merging pipe 21_{M} is provided with a plurality of inlets and one drain outlet.

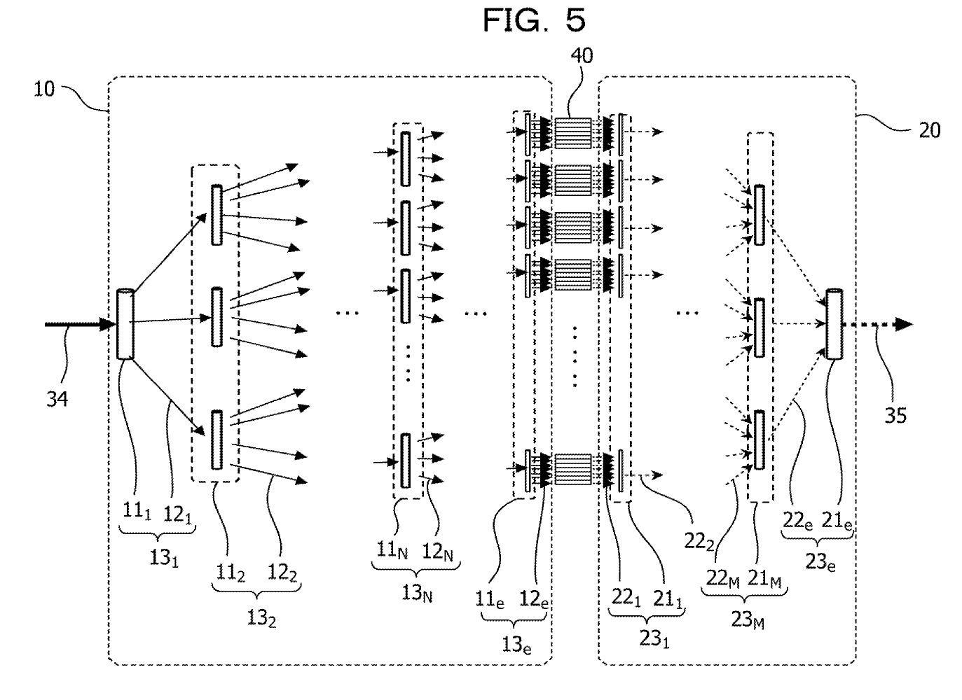

FIG. 5 illustrates an example of distribution and merging of a coolant. In FIG. 5, the coolant is distributed by a plurality of distributing layer distributing units, and is merged again by a plurality of merging layer merging units. FIG. 5 illustrates an example of an information processing device including distributing layer distributing units and merging layer merging units in three layers or more. The coolant flowing into a first distributing layer distributing unit 13₁ through the feed pipe 34 from the left is distributed by a distributing pipe 11₁, and flows into a second distributing layer distributing unit 13₂ through distributing connecting pipes 12₁. The distribution of the coolant continues to a final layer 13e. The coolant then flows to each electronic device 40. The cooling water after cooling the electronic devices 40 is collected by a merging unit 20. The merging unit 20 collects the cooling water in each group in a first merging layer merging unit 23₁. After merging continues to a final layer 23e, the coolant is sent to the heat exchanger 33 via the drain pipe 35.

The number of layers of the distributing unit 10 and the number of layers of the merging unit 20 may be the same, or may be different from each other. For example, the distributing unit 10 may be formed in three layers, and the merging unit 20 may be formed in two layers. For example, only the merging unit 20 may be formed in one layer.

When the distributing unit 10 is fabricated in a plurality of layers, a diameter SD_{N+1} of a distributing pipe 11_{N+1} of an (N+1)th distributing layer distributing unit on the downstream side is formed smaller than a diameter SD_{N} of a distributing pipe 11_{N} in an Nth distributing layer distributing unit. In the Nth distributing layer distributing unit, a diameter TD_{N} of a distributing connecting pipe 12_{N} is formed smaller than the diameter SD_{N} of the distributing pipe 11_{N}.

In consideration of pressure losses during distribution of the coolant, the diameter SD_{N+1} of the distributing pipe 11_{N+1} of the (N+1)th distributing layer distributing unit 13_{N+1} on the downstream side may be determined by the following Equation.

SD_{N+1}=SD_{N}/√(SN_{N})

where SD_{N} denotes the diameter of the distributing pipe 11 in the Nth distributing layer distributing unit, and SN_{N} denotes the number of distributions in the Nth distributing layer distributing unit.

When the merging unit 20 is formed in a plurality of layers, a diameter CD_{M-1} (M is an integer of 2 or more, and increases from the upstream side of the coolant to the downstream side) of a merging pipe 21_{M-1} in an (M−1)th layer is formed smaller than a diameter CD_{M} of a merging pipe 21_{M} present in an Mth merging layer merging unit. For example, a diameter CD_{M+1} of a merging pipe 21_{M+1} in an (M+1)th layer (downstream side) is formed larger than the diameter CD_{M} of the merging pipe 21_{M} present in the Mth merging layer merging unit. In the Mth merging layer merging unit, a diameter UD_{M} of a merging connecting pipe 22_{M} is formed smaller than the diameter CD_{M} of the merging pipe 21_{M}.

The diameter CD_{M+1} of the merging pipe 21_{M+1} in the (M+1)th layer may be determined by the following Equation.

CD_{M+1}=CD_{M}×√(CN_{M+1})

where CD_{M} denotes the diameter of the pipe in the Mth merging layer merging unit (layer on the upstream side), and CN_{M+1} denotes the number of merging flows from which the coolant merges in the (M+1)th merging layer merging unit (layer on the downstream side).

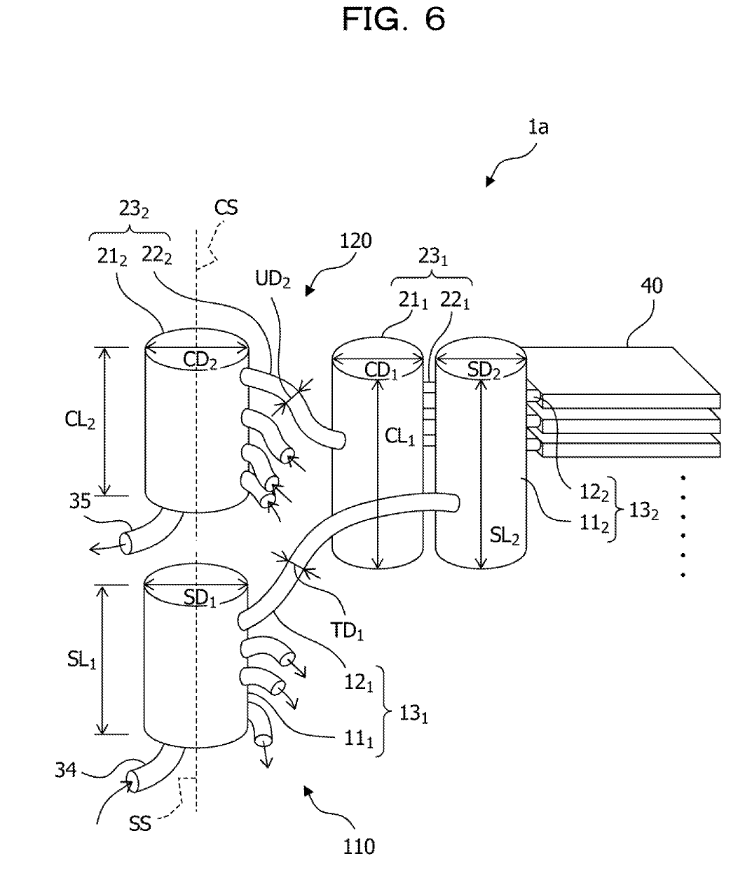

FIG. 6 illustrates an example of an information processing device. The information processing device illustrated in FIG. 6 may be a server device 1a. In the server device 1 illustrated in FIG. 2 and FIG. 3, the diameter SD₂ of the second distributing pipe 11₂ used in the distributing unit 10 is formed so as to be smaller than the diameter SD₁ of the first distributing pipe 11₁. On the other hand, in a distributing unit 110 of the server device 1a illustrated in FIG. 6, a diameter SD₁ of a first distributing pipe 11₁ of a first distributing layer distributing unit 13₁ and a diameter SD₂ of a second distributing pipe 11₂ of a second distributing layer distributing unit 13₂ are formed to be substantially a same dimension. First distributing connecting pipes 12₁, second distributing connecting pipes 12₂, and electronic devices 40 are the same as those of the server device 1 illustrated in FIG. 3, and therefore description thereof will be omitted. The dimensions (inside diameters) of the diameter SD₁ of the first distributing pipe 11₁ and the diameter SD₂ of the second distributing pipe 11₂ illustrated in FIG. 6 are preferably 1 to 200 mm.

Also in a merging unit 120 of the server device 1a illustrated in FIG. 6, as in the distributing unit 110, a diameter CD₁ of a first merging pipe 21₁ of a first merging layer merging unit 23₁ and a diameter CD₂ of a second merging pipe 21₂ of a second merging layer merging unit 23₂ are formed to be a same dimension. Merging connecting pipes 22₁ and merging connecting pipes 22₂ are the same as those of the server device 1 illustrated in FIG. 3, and therefore description thereof will be omitted. The dimensions (inside diameters) of the diameter CD₁ of the first merging pipe 21₁ and the diameter CD₂ of the second merging pipe 21₂ are preferably 1 to 200 mm. In addition, the diameter CD₁ of the first merging pipe 21₁ and the diameter SD₂ of the second distributing pipe 11₂ may be a same dimension. It is to be noted that the same dimension in this case includes completely the same dimension, and besides, dimensions that may be considered to be essentially the same dimension. For example, differences in size of 1 to 5 mm, which do not greatly affect pressure losses of the coolant flowing through the pipes, may be included in the same dimension.

Pipes having a same diameter are used as the first distributing pipe 11₁ and the second distributing pipe 11₂. However, a height SL₁ of the first distributing pipe 11₁ and a height SL₂ of the second distributing pipe 11₂ may be a same dimension, or may be different from each other. For example, one of the height SL₁ of the first distributing pipe 11₁ and the height SL₂ of the second distributing pipe 11₂ may be larger.

In addition, pipes having a same diameter are used as the first merging pipe 21₁ and the second merging pipe 21₂. However, a height CL₁ of the first merging pipe 21₁ and a height CL₂ of the second merging pipe 21₂ may be a same dimension, or may be different from each other. For example, one of the height CL₂ of the second merging pipe 21₂ and the height CL₁ of the first merging pipe 21₁ may be larger. This is because pressure losses of the coolant flowing in the distributing unit 110 or the merging unit 120 change depending on the diameters (CD₁, CD₂, SD₁, and SD₂) of the pipes, but are affected little by differences in length of those pipes, for example, differences in height (SL₁, SL₂, CL₁, and CL₂) of the pipes.

In the server device 1a illustrated in FIG. 6, the diameter SD₁ of the first distributing pipe 11₁ and the diameter SD₂ of the second distributing pipe 11₂ are a same dimension, and therefore the pressure losses may hardly vary. Therefore, when the plurality of first distributing connecting pipes 12₁ connecting the first distributing pipe 11₁ to a plurality of second distributing pipes 11₂ have essentially a same length and essentially a same diameter TD₁, the coolant may be supplied to each of the second distributing pipes 11₂ at a uniform flow rate. For example, even when the length of the first distributing connecting pipes 12₁ varies, amounts of supply of the coolant to the second distributing pipes 11₂ are controlled by changing the diameter TD₁ of the first distributing connecting pipes 12₁ or adjusting the pressure losses by providing a function of adjusting the pressure losses. Therefore, even when the number of branches from the first distributing pipe 11₁ is increased, for example, design thereof may be easy.

Because the diameter SD₁ of the first distributing pipe 11₁ and the diameter SD₂ of the second distributing pipes 11₂ are essentially a same dimension, the first distributing pipe 11₁ and the second distributing pipes 11₂ are procured according to same specifications. Because the first distributing pipe 11₁ and the second distributing pipes 11₂ are procured according to the same specifications, a purchased quantity of pipe material used for the first distributing pipe 11₁ and the like is increased. Thus, unit cost may be decreased and procurement cost may be reduced. The first merging pipe 21₁ and the second merging pipe 21₂ of the merging unit 120 of the server device 1a may also provide similar effects.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An information processing device comprising:
a first distributing layer distributer configured to distribute a coolant for cooling a plurality of electronic devices stacked in a height direction; and
a second distributing layer distributer coupled to the first distributing layer distributer and configured to distribute the coolant,
wherein the first distributing layer distributer includes a first distributing pipe which temporarily stores the coolant and a plurality of first distributing connecting pipes branched from the first distributing pipe, the first distributing pipe is disposed in such a manner that an axis of the first distributing pipe is parallel with the height direction, and the plurality of first distributing connecting pipes are arranged side by side in the height direction,
wherein the second distributing layer distributer includes a plurality of second distributing pipes which are coupled to the respective first distributing connecting pipes and temporarily store the coolant, each of the plurality of second distributing pipes is disposed in such a manner that an axis of the second distributing pipe is parallel with the height direction, and the plurality of second distributing pipes are arranged in the height direction.

2. The information processing device according to claim 1, wherein
a diameter of the first distributing connecting pipes is formed so as to be smaller than a diameter of the first distributing pipe, and
a diameter of the second distributing pipe is formed so as to be smaller than the diameter of the first distributing pipe.

3. The information processing device according to claim 1, wherein
a diameter of the second distributing pipe is determined from a following Equation:
SD₂=SD₁/√(SN₁)
where SD₂ is the diameter of the second distributing pipe, SD₁ is a diameter of the first distributing pipe, and SN₁ is a number of distribution paths into which the coolant is distributed in the first distributing layer distributer.

4. The information processing device according to claim 1, a diameter of the first distributing pipe and a diameter of the second distributing pipe are the same with each other.

5. The information processing device according to claim 1, further comprising:
a first merging layer combiner configured to merge the coolant after cooling the plurality of electronic devices; and
a second merging layer combiner coupled to the first merging layer merging unit and configured to further merge the coolant.

6. The information processing device according to claim 5, wherein
the first merging layer combiner includes a plurality of first merging pipes configured to temporarily store the coolant, each of the plurality of first merging pipes is disposed in such a manner that an axis of the first merging pipe is parallel with the height direction, and the plurality of first merging pipes are arranged side by side in the height direction, and
the second merging layer combiner includes a plurality of second merging connecting pipes coupled to the respective first merging pipes and a second merging pipe which is coupled to the plurality of second merging connecting pipes and temporarily stores the coolant, the plurality of second merging connecting pipes are arranged side by side in the height direction, and each of the second merging pipes is disposed in such a manner that an axis of the second merging pipe is parallel with the height direction.

7. The information processing device according to claim 6, wherein
a diameter of the second merging connecting pipes is formed so as to be smaller than a diameter of the second merging pipe, and
a diameter of the first merging pipes is formed so as to be smaller than the diameter of the second merging pipe.

8. The information processing device according to claim 6, wherein
a diameter of the second merging pipe is determined from a following Equation:
CD₂=CD₁×√(CN₁)
where CD₁ is a diameter of the first merging pipes of the first merging layer combiner, CD₂ is the diameter of the second merging pipe of the second merging layer combiner, and CN₁ is the number of merging flows of the plurality of first merging pipes from which the coolant merges, the plurality of first merging pipes being included in the first merging layer combiner.

9. The information processing device according to claim 6, a diameter of the first distributing pipe and a diameter of the second distributing pipe are the same with each other.

10. The information processing device according to claim 6, wherein
the axis of the second merging pipe is disposed so as to be the same as the axis of the first distributing pipe.

11. An electronic device cooling method comprising:
temporarily storing a coolant for cooling a plurality of first electronic devices stacked in a height direction and a plurality of second electronic devices stacked in the height direction in a first distributing pipe extending in the height direction;
sending out the coolant to a second distributing pipe extending in the height direction via first distributing connecting pipes branched from the first distributing pipe;
sending out the coolant to a third distributing pipe extending in the height direction via second distributing connecting pipes branched from the first distributing pipe;
sending out the coolant to the plurality of first electronic devices via a plurality of third distributing connecting pipes arranged in parallel with each other in the height direction and coupled to the second distributing pipe; and
sending out the coolant to the plurality of second electronic devices via a plurality of fourth distributing connecting pipes arranged in parallel with each other in the height direction and coupled to the third distributing pipe.
